(19) United States
(12) Patent Application Publication
(10) Pub. No.: US 2014/0373901 A1
(43) Pub. Date: Dec. 25, 2014

(54) Optical Concentrator and Associated Photovoltaic Devices

(71) Applicant: The University of Exeter, Devon (GB)

(72) Inventors: Tapas Kumar Mallick, Cornwall (GB); Nazmi Sellami, Cornwall (GB)

(73) Assignee: The University of Exeter, Devon (GB)

(21) Appl. No.: 14/367,089

(22) PCT Filed: Dec. 20, 2012
(86) PCT No.: PCT/GB2012/053221

§ 371 Date: Jun. 19, 2014

(30) Foreign Application Priority Data
Dec. 21, 2011 (GB) 1122092.8

(51) Int. Cl. H01L 31/052; B29C 39/26; G02B 3/00

(52) U.S. Cl. CPC H01L 31/0524; G02B 3/0037; B29C 39/26; B29L 2011/00
USPC 136/246; 136/259; 359/619; 249/203

(57) ABSTRACT

Disclosed is a transmissive optical concentrator comprising an elliptical collector aperture and a non-elliptical exit aperture, the concentrator being operable to concentrate radiation incident on said collector aperture. The body of said concentrator may have a substantially hyperbolic external profile. Also disclosed is a photovoltaic cell employing such a concentrator and a photovoltaic building unit comprising an array of optical transmissive concentrators, each having an elliptical collector aperture; and an array of photovoltaic cells, each aligned with an exit aperture of a concentrator, wherein the area between adjacent collector apertures is transmissive to visible radiation.

The present invention relates to photovoltaic devices and more particularly to those having an optical component that is capable of concentrating solar energy in an efficient manner and a method of making photovoltaic devices using such components.

As an alternative to fossil fuels, the sun is considered the most abundant natural resource and Solar energy conversion has become commonplace as mass manufacture and increasing efficiency of photovoltaic (PV) materials that convert light to electricity has driven the cost down of PV materials to a level that solar panel arrays are now used to provide power in “off grid” applications, back-up power for portable devices or are being installed or retrofitted to buildings to augment existing power—such installations are known as Building Integrated Photovoltaic (BIPV) or Building Applied Photovoltaics (BAPV).

Solar Energy is actually quite diffuse and due to the seasonal rotation of the Earth on its axis can also vary significantly with the latitude on the planet. It has been estimated that to generate about a gigawatt of power using modern PV systems would require an area of approximately four square miles of silicon and the use of such large amounts of silicon is one of the largest hurdles in the mass uptake of solar PV as a possible replacement for fossil fuels.

Solar PV materials are struggling to increase their conversion efficiency and one potential route being taken to reduce the cost of generating electricity from PV systems is to use less PV material in the device itself, however using a smaller area of PV reduces the surface available to the solar energy and this can lead to a significant drop-off in PV device conversion efficiency and to counter this effect, solar concentrators have been used as a means to focus the sun's energy onto the smaller area of PV material.

Solar concentration is well known and there already exist a number of optical components that can be used to concentrate solar energy, including curved mirrors, patterned plastic sheets, curved metal reflectors, lens arrays and specialised lenses, such as Fresnel lenses. Incorporation of these optical components has given rise to a new class of PV systems known as “Concentrating Photovoltaic” or CPV devices. A summary description of such systems is given by Muhammad-Sukki et al. in the International Journal of Applied Sciences (Vol 1, Issue 1) and we incorporate this by reference.

The fabrication of CPV devices offers advantages over flat plate, or non-concentrating PV devices. These advantages can include, but are not limited to: 1) concentrator PV devices can increase power output while at the same time reducing the number of solar cells needed; and 2) concentrator PV devices can utilize solar cells that are of a much smaller surface area, that are easier to mass-produce compared to large surface area solar cells.

### SUMMARY OF INVENTION

In a first aspect of the invention there is provided a transmissive optical concentrator comprising an elliptical collector aperture and a non-elliptical exit aperture, said concentrator being operable to concentrate radiation incident on said collector aperture.

Said exit aperture may be rectangular, and preferably square.

In the above, elliptical includes circular and rectangular includes square.

The body of said concentrator, between the collector aperture and the exit aperture may have a substantially hyperbolic external profile. Said hyperbolic profile may be different at different sections of rotational angle of the elliptical collector aperture.

Said concentrator may be a non-imaging concentrator.

The ratio of the height of the concentrator between collector aperture and exit aperture to the length of one side of the exit aperture may be chosen to be less than 3:1, and, less than two or less than 1.5:1. In this embodiment the collector aperture may have a ratio of its major axis to its minor axis greater than 1.5:1, and in an embodiment between 1.5:1 and 2.5:1. In a different embodiment where highest peak efficiency is desirable, this ratio may be chosen to be less than 2:1. In this embodiment the collector aperture may have a ratio of its major axis to its minor axis less than 1.5:1, and possibly substantially circular.

The ratio of the area of the collector aperture to the area of the exit aperture may be chosen to be 6:1 or less, and possibly 4:1 or less.

The material of the optical concentrator may contain one or more additives that promote durability of the material itself or perform another function such as imparting a fluorescence effect, a luminescence effect or other beneficial property.

In a second aspect of the invention there is provided a photovoltaic device comprising a concentrator of the first aspect and a photovoltaic cell arranged to receive collected radiation from the exit aperture.

The dimensions and area of the exit aperture may be matched to the dimensions and area of the photovoltaic cell.

In a third aspect of the invention there is provided a mould for manufacturing one or more concentrators of the first aspect of the invention. Said mould may form a single piece array of said concentrators.

In a fourth aspect of the invention there is provided a photovoltaic building unit comprising:

an array of optical transmissive concentrators, each having an elliptical collector aperture; and

an array of photovoltaic cells, each aligned with an exit aperture of a concentrator; wherein the area between adjacent collector apertures is transmissive to visible radiation.

Said array of transmissive concentrators may comprise a single piece with the transmissive areas between adjacent concentrators being formed from the same material as the concentrators. This one-piece array of optical transmissive concentrators can function as both a concentrator array and a cover glass.

Said concentrators may be those of the first aspect of the invention.

For the avoidance of doubt, the term photovoltaic building unit should be taken to include building integrated photovoltaic units and building applied photovoltaic units.

Also described is a method of making a PV concentrator device of the present invention that is incorporated as part of an insulated glazing unit (a window) to provide both electrical energy and light transmission properties. One particular benefit of this method is that it provides environmental protection of the PV material whilst acting as part of a BIPV or BAPV energy solution.

### BRIEF DESCRIPTION OF THE DRAWINGS

Embodiments of the invention will now be described, by way of example only, by reference to the accompanying drawings, in which:

FIG. 1 is a 3-Dimensional schematic representation of a concentrator device according to an embodiment of the invention;

FIG. 2 is a solid 3-Dimensional representation of a concentrator device according to an embodiment of the invention;

FIGS. 3a and 3b represents a simplified schematic diagram of the main parameters of the Hyperboloid concentrator where a is the minor axis of the elliptical axis, b is the major axis of the elliptical axis, H is the Height of the aperture and A is the length of the side of the exit aperture; in plan view and cross-section respectively;

FIG. 4 is a 3 dimensional graph of Elliptical Aspect Ratio (b/a) against Height Aspect Ratio (H/A) against geometric concentration C_{g} for concentrator devices according to embodiments of the invention;

FIGS. 5a and 5b show respectively a plan view and cross sectional side view of a photovoltaic building unit according to embodiment of the invention;

FIGS. 6a and 6b show respectively an exploded view and assembled view of a photovoltaic building unit according to a further embodiment of the invention; and

FIG. 7 shows of a mould that can be used to create a concentrator array according to an embodiment of the invention;

### DETAILED DESCRIPTION OF THE EMBODIMENTS

While the present invention may be embodied in many different forms, a number of illustrative examples are described. Disclosed herein is an optical concentrator for a photovoltaic device that is easily and efficiently produced by well-known plastics or glass production techniques. Also disclosed is a method of making a PV device that incorporates such an optical concentrator.

Such a device has particular applicability to the fields of building integrated or building applied photo-voltaic energy as the device allows both simultaneous light transmission and photovoltaic energy generation using a reduced area of photovoltaic material.

Within any PV device described herein the concentrator is arranged to direct and concentrate solar energy to the active surface of a PV material and such a PV device may comprise other materials such adhesive or sealing layers, reflecting or non-reflecting layers, or structures may be present to provide support, adhesion, environmental protection, encapsulation, electrical connection etc. to make up a complete PV device. Such features are not described here. as they are well known to the skilled person.

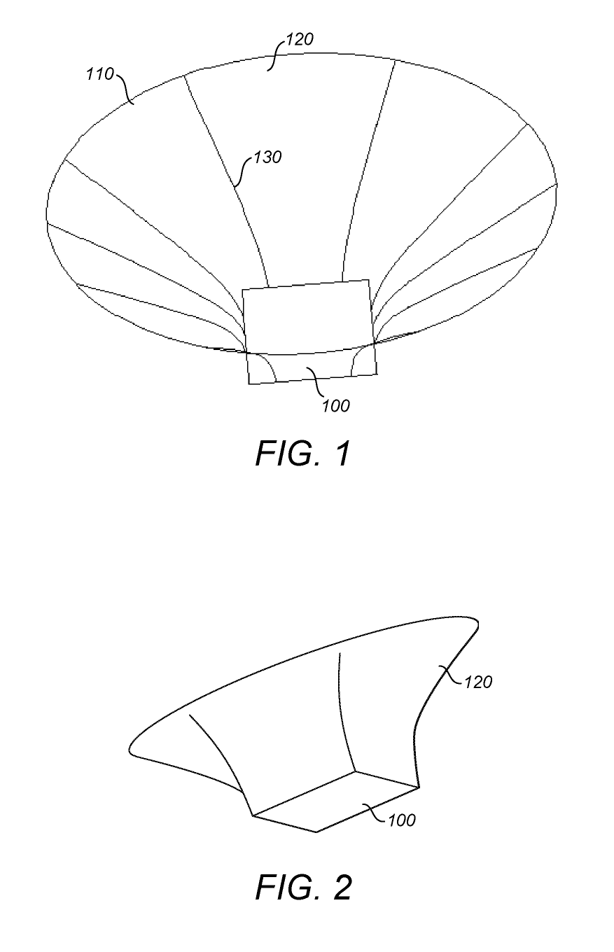

FIGS. 1 and 2 illustrate the basic configuration of the concentrator disclosed herein. The concentrator device is herein referred to as a “Square Elliptical Hyperboloid Concentrator” or SEH. The concentrator is transmissive and has a non-round exit aperture 100 to match with the surface of a PV material, an elliptical collector aperture 110 that can provide a large acceptance angle for collecting diffuse solar energy and a hyperbolic section 120 that connects the collector and exit apertures. In FIG. 1 the hyperbolic surface is represented by a small number of hyperbola shaped lines 130 which connect the exit aperture 100 and collector aperture 110. In a main embodiment the exit aperture 100 is rectangular, and more preferably square. “Elliptical”, with reference to the collector aperture 110, should be understood to include a circular aperture. Joining a round shape (ellipse or circle) to a shape with sharp angles (square) to create a smooth 3-D geometry is an innovative configuration.

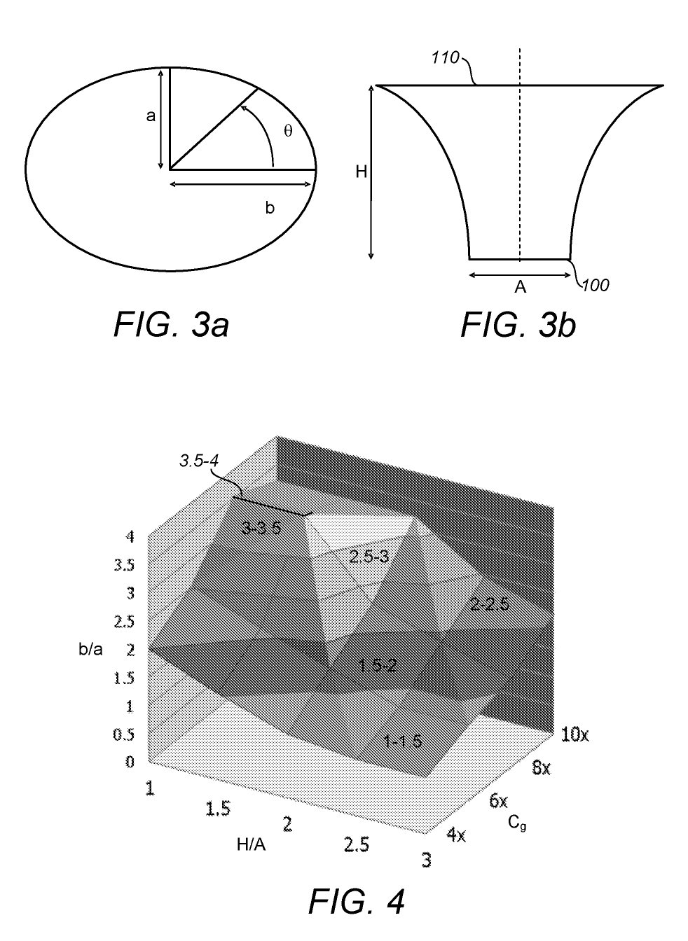

FIGS. 3a and 3b shows the device in plan and cross section respectively, and show the key parameters of the SEH. The different dimension characteristics are:
the elliptical aspect ratio (EAR) is the b/a ratio, that is the ratio of the transverse radius to the conjugate radius,
rotational angle θ.
the height aspect ratio (HAR)—the ratio of the SEH height H and the width A of the output aperture,

The SEH has a different hyperbolic profile at different sections of rotational angle θ. In one embodiment the 3-D parametric equation of the SEH is:

$$\{ \begin{matrix}θ ∈ [ \frac{7 π}{4} + n π , \frac{π}{4} + n π ] n = 0 , 1 ; K = \vert tan θ \vert ; M = sin θ ; N = cos θ \\ t ∈ [ 0 , H ] \\ θ ∈ [ \frac{π}{4} + n π , \frac{3 π}{4} + n π ] n = 0 , 1 ; K = \frac{1}{\vert tan θ \vert} ; M = cos θ ; N = sin θ\end{matrix} \\ \{ \begin{matrix}x = \frac{A}{2} \times cos θ \times ( C + \frac{\sqrt{{( H \times A )}^{2} + ( 4 \times {t}^{2} \times D ) - {( A \times t )}^{2}}}{H \times A} ) \\ y = x \times tan θ \\ z = t\end{matrix} \qquad ( 1 )$$

### Where:

$$\begin{matrix}C = \sqrt{{( 1 + {K}^{2} )}_{1}} & ( 2 ) \\ D = {( \sqrt{( F + {( E - \frac{A \times K}{2} )}^{2} )} + \frac{A}{2} )}^{2} & ( 3 ) \\ E = \frac{a \times b \times \vert N \vert}{\sqrt{{( b \times cos θ )}^{2} + {( a \times sin θ )}^{2}}} & ( 4 ) \\ F = {( \frac{a \times b \times \vert N \vert}{\sqrt{{( b \times cos θ )}^{2} + {( a \times sin θ )}^{2}}} - \frac{A}{2} )}^{2} & ( 5 )\end{matrix}$$

A MATLAB® program was written to generate the x, y, z coordinates of the SEH using the 3-D parametric equation above. The equation was validated upon completion of the illustrations of the SEH, The point cloud option and the data therein was used in the CAD software to draw the SEH.

### Profile Optimisation

A series of design experiments at different optical concentrations (specifically 4×, 6×, 8× and 10×) has been performed, so as to optimise the profile of the SEH and obtain a balance between the highest optical efficiency, the compactness of the shape and the widest acceptance angle. In addition to the different dimension characteristics already mentioned, the following parameters are also relevant:
the acceptance angle—the angle of incidence of the light on the collector aperture, where zero degrees in perpendicular to the surface of the collector aperture,
the geometrical concentration ratio (C_{g}), which is the ratio of the areas of the collector aperture and output aperture—here it can be seen to equal πab/A²,
the optical efficiency of the medium η defined as the radiant flux out divided by the radiant flux in and represents the percentage of light in the medium transmits,
the optical concentration ratio (Cₒₚₜ)—defined as ηC_{g},
the energy flux distribution.

### Optimisation of Elliptical Aspect Ratio (EAR)

A first simulation was run to optimise the shape of the ellipse at the entry aperture, starting from a circle (a=b), moving to a different ellipse shape of the same area. The optical efficiency for different geometric concentration ratios 4×, 6×, 8× and 10x at 0° angle of incidence was determined for each ellipse. It was seen that the optical efficiency, overall, is higher for lower geometrical concentration ratios. Also, the greater the HAR (i.e. the taller the height of the concentrator), the better is the optical efficiency for the same geometrical concentration ratio for an angle of incidence 0°. The more the elliptic entry aperture is close to a circular shape (EAR close to 1), the higher is the optical efficiency for the lower geometrical concentration ratios. The optimised profiles of the elliptical entry aperture are summarised and illustrated in FIG. 4. This is a 3 dimensional graph of EAR (b/a) against HAR (H/A) against C_{g}. Each profile was studied in detail in order to observe the effect of the variation of the incident angle on the optical efficiency.

### Optimisation of the Height Aspect Ratio (HAR)

The variation of the optical efficiency at different incident angles for each of the optimised EAR was considered. It was determined that the optical efficiency is highest when HAR>2. However, the optical efficiency drops as soon as the angle of incidence varies. For lower values of HAR (e.g. HAR<2), the optical efficiency remains more constant as the angle of incidence varies. For example, for a concentration 4× and a HAR=1, the optical efficiency drops only by 10% for a variation in the angle of incidence of 140° (−70°, +70°). However, for HAR=3 (same concentration) the optical efficiency drops by 60% for the same variation of the angle of incidence.

### Optimisation of the Geometrical Concentration (C_{g}):

The effect of the geometrical concentration ratio on the optical efficiency was determined. It was seen that the optical efficiency increases as the geometrical concentration ratio decreases for all the incident angles, regardless of HAR. The most efficient SEH had a geometrical concentration ratio 4×, an EAR=1 (i.e. circular entry aperture) and a HAR=3 or 2.5.

### Optical Concentration Ratios (Cₒₚₜ):

An equally important factor to consider is how much concentration will reach the exit aperture. This is defined as the geometrical concentration ratio multiplied by the optical efficiency. This will represent the amount of radiation that will reach the solar cells at the exit aperture after concentration.

### Energy Flux Distribution of the System:

Another consideration is the flux distribution on the PV cell. Ideally the energy flux should be distributed as evenly as possible over the cell. It was determined, for example, that the SEH which showed the highest optical concentration ratio (and therefore appeared most efficient in transmitting energy), most of the rays were focused in one small area of the solar cell, reducing the cell's efficiency. It was determined that this was because this SEH has a large HAR, and that more uniform distribution was observed for SEHs of lower heights.

Optimisation summary

It was determined that the EAR and C_{g} should be optimised for each HAR. It was also determined that the greater the HAR, the greater the peak optical concentration ratio. However this was at the expense of a less even flux distribution and a greater fall off of optical efficiency with increased incidence angle. The reverse of this is that a shorter SEH tends to improve the flux distribution and means that there is less optical efficiency variance with the angle of incidence. However the peak optical efficiency is lower.

### Window Integrated Concentrating Photovoltaic (WICPV)

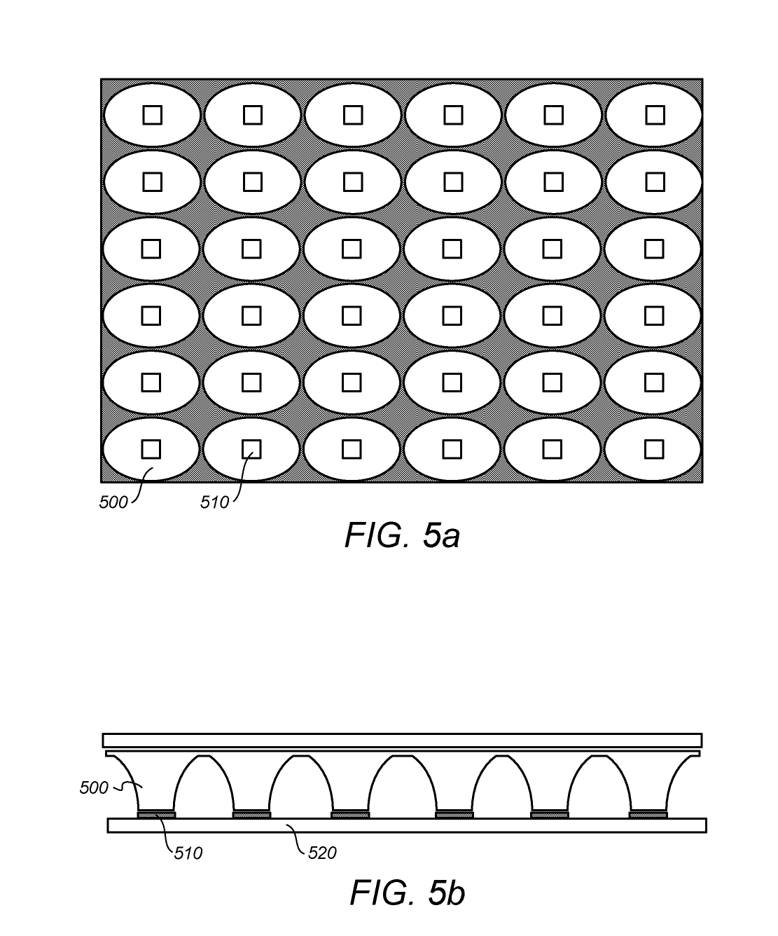

FIG. 5 shows a plan view of the top surface of Window Integrated Concentrating Photovoltaic (WICPV). This comprises an array of SEHs 500 and a correspond array of PV cells 510. The array of SEHs 500 may comprise a single moulding, and the array of SEHs 500 and array of PV cells 510 may be optionally sandwiched between glass (or other transmissive material) layers. The non-shaded area is the area of the collector apertures of each SEH, and represents the area that focuses or directs the light to the PV surface located at the exit aperture of each SEH. The shaded area is the non-focusing (transmissive) area where solar energy (light of the electromagnetic spectrum) can pass through. This is desirable as it allows a degree of light transmission through the array allowing the WICPV to be used in windows for buildings etc. or as a stand alone unit for stationary power.

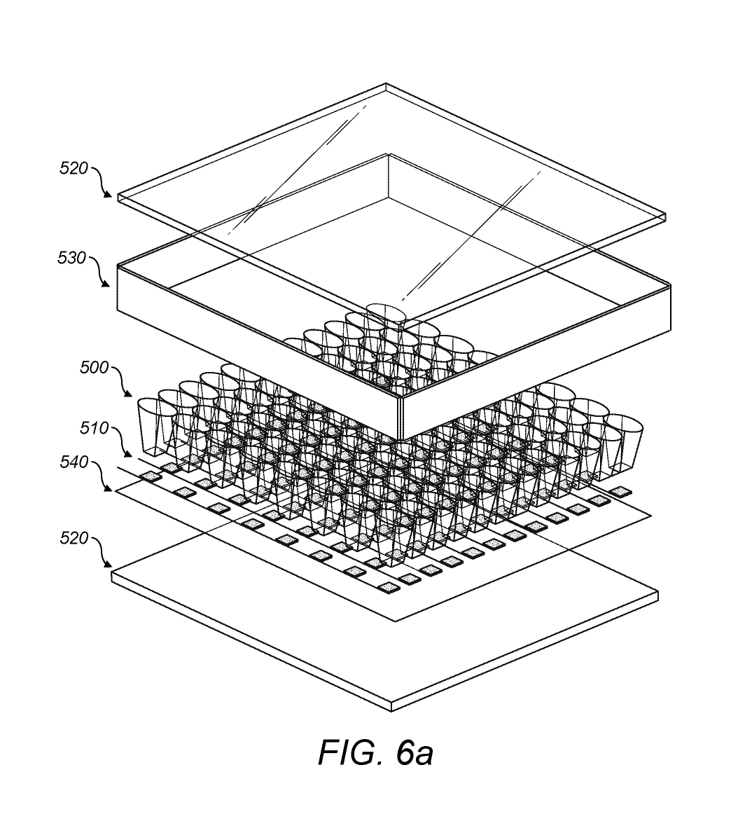

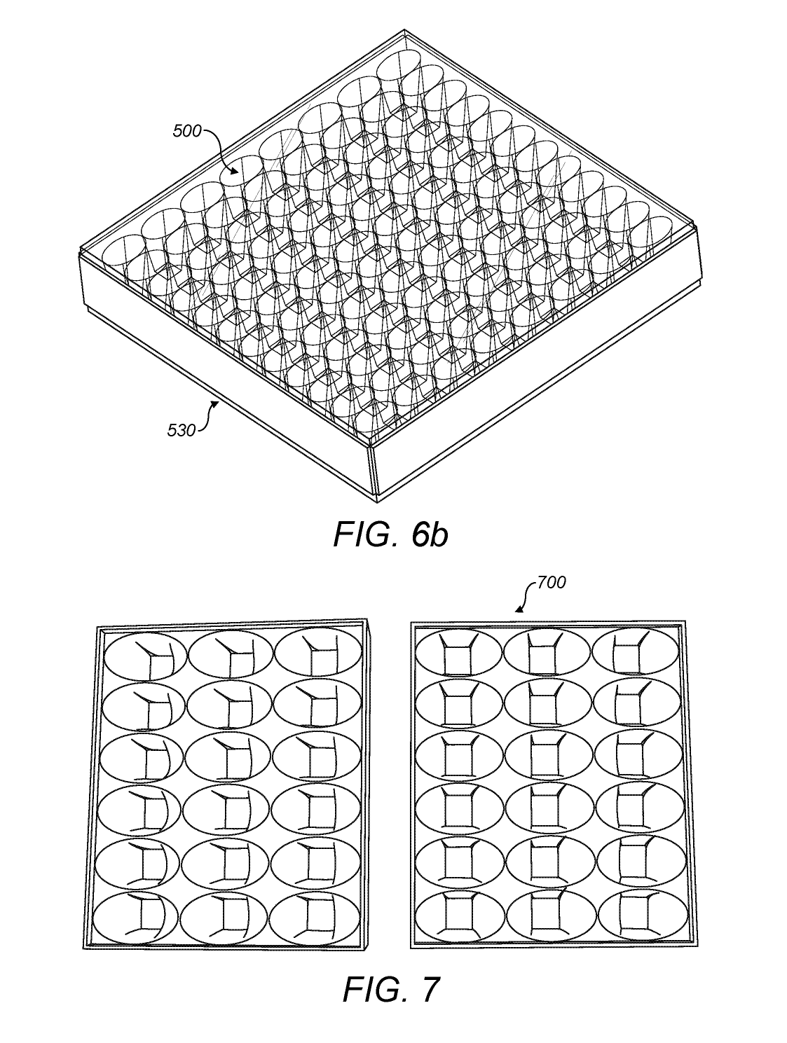

FIGS. 6a, 6b and 6c show how the WICPV device of FIG. 5 in side view cross-section, exploded view and assembled view respectively. In addition to the one piece array of SEHs 500 and array of PV cells 510, there can be seen glass layers 520, a frame 530 and an encapsulation layer 540 (all optional). The device may be a stationary concentrating PV device or used as part of an insulated glazing unit where the top and lower glass represent two opposite panes of the glazing unit.

It will be obvious in the above figures that if the bulk material of the SEH concentrator is of a sufficient durability to provide environmental protection (e.g. a glass material or a clear plastics materials such as PMMA or Polycarbonate) then the top glass may be unnecessary and this reduces the parts count and manufacturing cost of this invention.

The point cloud data, x, y, z co-ordinates, can be used to program CNC forming machinery (a routing, milling or cutting device) to manufacture a mould 700 as depicted in FIG. 7 from a suitable material such as a metal or a plastics material. The optical material for the SEH may be an ambient curing epoxy polymer resin made according to the manufacturer's instructions Alternatively it could be glass, a plastic or any other material with suitable optical and environmental properties. To manufacture an array of SEHs, sufficient volume of the activated epoxy resin can be poured into the mould, allowed to harden and then separated from the mould.

The concepts disclose herein PV devices with an optical concentrator that is easily and economically produced, as well as methods of optimising the shape of the optical concentrator and making the PV devices that overcome the limitations associated with conventional concentrating and non-concentrating PV devices. Using the shaped optical concentrator of the present invention in a PV device of the invention results in a reduction of the manufacturing parts count and a cost saving (compared to other CPV and non-concentrating devices), as well as increased energy output for a given area of PV material. The optical concentrator is efficient in concentrating solar energy.

Where the width and breadth dimensions of the exit aperture on the lower surface of the optical concentrator are such that they closely match that of the energy conversion surface of the PV device; due to the relative cost of PV materials, exit apertures of this design increase PV efficiency and in turn further reduce PV device costs.

The height of the section joining the elliptical collecting aperture and the exit aperture of the optical concentrator may be such that the optical concentrator provides maximum efficiency in solar energy concentration.

The optical concentrator of the present invention may be mass manufactured using materials with suitable optical and environmental resistance properties and can function in a PV device as a concentrator.

A skilled person will appreciate that variations of the disclosed arrangements are possible without departing from the invention. Accordingly the above description of specific embodiments are made by way of example only and not for the purposes of limitation. It will be clear to the skilled person that minor modifications may be made without significant changes to the operation described.

1. A transmissive optical concentrator comprising an elliptical collector aperture and a non-elliptical exit aperture, said concentrator being operable to concentrate radiation incident on said collector aperture.

2. A transmissive optical concentrator as claimed in claim 1 wherein said exit aperture is rectangular.

3. A transmissive optical concentrator as claimed in claim 1 wherein the body of said concentrator, between the collector aperture and the exit aperture has a substantially hyperbolic external profile.

4. A transmissive optical concentrator as claimed in claim 3 wherein said hyperbolic profile is different at different sections of rotational angle of the elliptical collector aperture.

5. A transmissive optical concentrator as claimed in claim 1 wherein said concentrator is a non-imaging concentrator.

6. A transmissive optical concentrator as claimed in claim 1 wherein the ratio of the height of the concentrator between collector aperture and exit aperture to the length of one side of the exit aperture is less than 3:1.

7. A transmissive optical concentrator as claimed in claim 1 wherein the ratio of the height of the concentrator between the collector aperture and exit aperture to the length of one side of the exit aperture is less than 1.5:1.

8. A transmissive optical concentrator as claimed in claim 6 wherein the collector aperture has a ratio of its major axis to its minor axis greater than 1.5:1.

9. A transmissive optical concentrator as claimed in claim 8 wherein the collector aperture has a ratio of its major axis to its minor axis between 1.5:1 and 2.5:1.

10. A transmissive optical concentrator as claimed in claim 1 wherein the collector aperture has a ratio of its major axis to its minor axis less than 2:1.

11. A transmissive optical concentrator as claimed in claim 1 wherein the collector aperture has a ratio of its major axis to its minor axis less than 1.5:1.

12. A transmissive optical concentrator as claimed in claim 1 wherein the ratio of the area of the collector aperture to the area. of the exit aperture is 6:1 or less.

13. A transmissive optical concentrator as claimed in claim 1 wherein the ratio of the area of the collector aperture to the area of the exit aperture is 4:1 or less.

14. A transmissive optical concentrator as claimed in claim 1 wherein the optical concentrator comprises a material containing one or more additives which impart a fluorescence effect and/or a luminescence effect.

15. A photovoltaic device comprising a concentrator as claimed in claim 1 a photovoltaic cell arranged to receive collected radiation from the exit aperture.

16. A photovoltaic device as claimed in claim 15 wherein the dimensions and area of the exit aperture are matched to the dimensions and area of the photovoltaic cell.

17. A mould configured for manufacturing one or more concentrators as claimed in claim 1.

18. A mould as claimed in claim 7 being configured to form a single piece array of said concentrators.

19. A photovoltaic building unit comprising:
an array of optical transmissive concentrators, each having an elliptical collector aperture; and
an array of photovoltaic cells, each aligned with an exit aperture of a concentrator;
wherein the area between adjacent collector apertures is at least partially transmissive to visible radiation.

20. A photovoltaic building unit as claimed in claim 19 wherein said array of transmissive concentrators comprises a single piece with the at least partially transmissive areas between adjacent concentrators being formed from the same material as the concentrators.

21. A photovoltaic budding unit as claimed in claim 20 wherein the one-piece array of optical transmissive concentrators functions as both a concentrator array and as a cover for the unit.

22. A photovoltaic building unit as claimed in claim 19 wherein each said concentrators comprise a concentrator as claimed in claim 1.

23. A photovoltaic building unit as claimed in claim 19 wherein the photovoltaic building unit comprises a building integrated photovoltaic unit or a building applied photovoltaic unit.
